(19) United States
(12) Patent Application Publication
(10) Pub. No.: US 2021/0410320 A1
(43) Pub. Date: Dec. 30, 2021

(54) IMMERSION COOLING SYSTEM WITH COOLANT BOILING POINT REDUCTION FOR INCREASED COOLING CAPACITY

(71) Applicant: Intel Corporation, Santa Clara, CA (US)

(72) Inventors: Jin YANG, Hillsboro, OR (US); David SHIA, Portland, OR (US)

(21) Appl. No.: 17/473,870

(22) Filed: Sep. 13, 2021

(51) Int. Cl. H05K 7/20

(52) U.S. Cl. CPC H05K 7/203; H05K 7/20818; H05K 7/20327; H05K 7/20318

(57) ABSTRACT

A method of operating an immersion cooling system is described. The method includes operating one or more electronic components that are immersed in a liquid coolant. The operating of the one or more electronic components causes the liquid coolant to boil. The method includes condensing vapor from the boiling liquid coolant in an ambient region of a chamber. The method includes drawing gas from the ambient region of the chamber to reduce a pressure of the gas within the ambient region of the chamber. The reduction of the pressure of the gas is to reduce a boiling point of the liquid coolant. The reduction of the boiling point of the liquid coolant is to increase the cooling capacity of the immersion cooling system.

### BACKGROUND

System design engineers face challenges, especially with respect to high performance data center computing, as both computers and networks continue to pack higher and higher levels of performance into smaller and smaller packages. Creative packaging and cooling systems are therefore being designed to keep pace with the thermal requirements of such aggressively designed systems.

### FIGURES

A better understanding of the present invention can be obtained from the following detailed description in conjunction with the following drawings, in which:

FIG. 1 shows a prior art cooling system;

FIG. 2 shows an improved cooling system;

FIG. 3 shows another improved cooling system;

FIG. 4 shows information regarding operation of the improved cooling systems of FIGS. 2 and 3;

FIG. 5 shows a pump for the improved cooling system of FIG. 3;

FIG. 6 shows a cooling system;

FIG. 7 shows a system;

FIG. 8 shows a data center;

FIG. 9 shows a rack.

### DETAILED DESCRIPTION

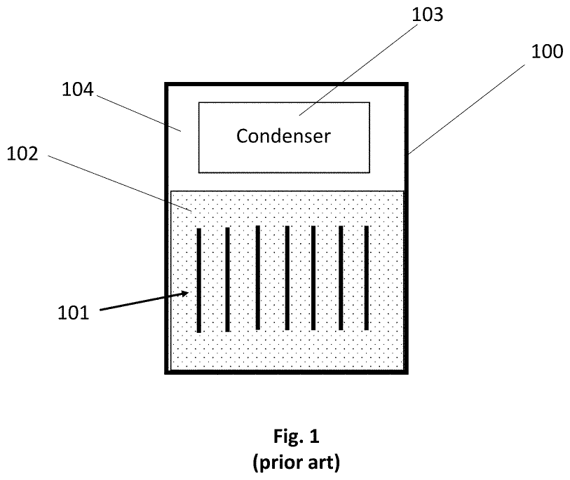

FIG. 1 depicts an electronic system such as a data center chassis/board with many attached active components being cooled in an immersion cooling system. As observed in FIG. 1, one or more electronic circuit boards 101 with mounted electrical components (e.g., semiconductor chips) are powered on and operating while the boards 101 and their components are immersed in a bath of thermally conducting but electrically insulating liquid 102 within a chamber 100. The complete immersion of the boards 101 and their components maximizes the surface area of the electrical system over which heat from the operating semiconductor chips can be released into the cooling medium (coolant 102). Additionally, as compared to air cooled systems, a liquid generally has a much higher latent heat and specific heat than air, resulting in a much lower thermal resistance for electronics cooling.

Here, heat from the operating semiconductor chips is transferred from the electronic system to the immersion bath 102. During initial heat up when power dissipation is not high and the heat transfer from the electronic devices to the surrounding liquid is via convection, the temperature of the bath coolant 102 warms in response to the heat from the electronic system but does not boil (the temperature of the bath coolant 102 remains below the liquid's boiling point). As the power keeps increasing for a certain period, which, e.g., can be applicable if the electronic system is continuously operating above a certain power, the liquid in the thermal bath 102 boils and converts from a liquid to a vapor (the temperate of the liquid surrounding the electronic device surface exceeds the liquid's boiling point). The vapor from the bath will be condensed through a condenser 103. The resulting liquid coolant is returned to the bath 102 which effectively removes heat from the packaged electronic devices and the overall electrical system.

Generally, the immersion bath 102 transfers heat away from the operating electronics more efficiently through the boiling process with the phase change from a liquid to vapor under a higher latent heat of liquid than specific heat (the second process described above has better heat transfer efficiency than the first process described above).

Said another way, heat from the operating electronics is rapidly transferred to the ambient 104 through the boiling activity, then, the condenser 103 rapidly removes the heat in the ambient 104 from the overall system (the ambient 104 is understood to be the open space above the bath 102 within the chamber 100). As such, electronic components are cooled more efficiently with a coolant that can be induced to boil more easily. More specifically, electronic components will have their heat more efficiently transferred/removed by lowering the coolant's boiling point.

The boiling points of the most widely used immersion coolants, although comparatively low for a liquid (e.g., approximately 50° C.), unfortunately do not have a low enough boiling point to efficiently cool higher wattage electronic components of the future (e.g., 750 W or greater per m³ of coolant).

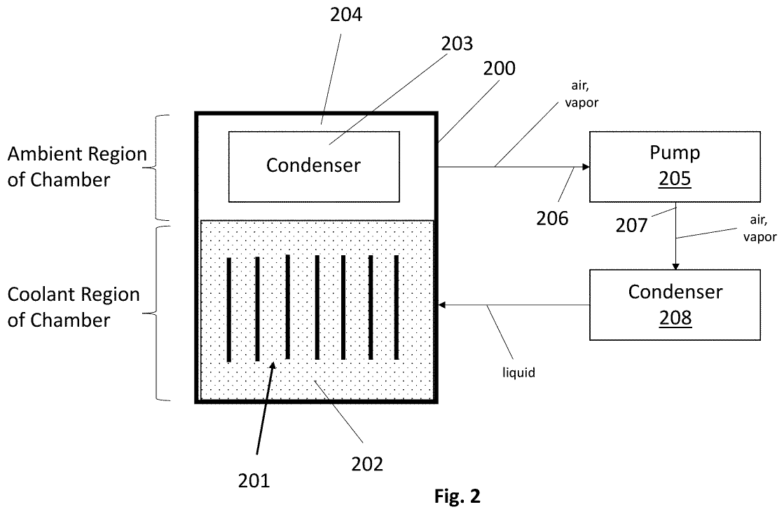

FIG. 2 therefore shows an improved immersion cooling system that lowers the boiling point of the liquid in the immersion bath 202. By lowering the boiling point of the immersion bath liquid 202, the immersion bath 201 will exhibit greater boiling activity for a same immersed electronic component wattage which, in turn, corresponds to higher heat transfer efficiency (greater cooling capacity of the overall system).

As is known in the art, a liquid's boiling point is typically specified when the liquid's ambient is at atmospheric pressure (101 KPa). As such, the aforementioned boiling point of approximately 50° C. for the most widely used immersion coolants is observed when their respective ambient is at atmospheric pressure. Here, the ambient 104 of the prior art immersion cooling system of FIG. 1 is nominally at atmospheric pressure. As such, the immersion liquid 102 typically exhibits a boiling point around 50° C.

Notably, the boiling temperature of the liquid is dependent on the pressure of the ambient 204. Specifically, the higher the pressure of the ambient, the more difficult it becomes for bubbles to nucleate and escape the surface of the liquid. By contrast, the lower the pressure inside the chamber applied to the liquid or called ambient, the less speed is needed by the molecules to escape the surface of the liquid. The former (higher ambient pressure) corresponds to a higher boiling point whereas the later (lower ambient pressure) corresponds to a lower boiling point. As such, the boiling point of any liquid can be reduced by lowering the pressure of the ambient.

As observed in FIG. 2, the improved immersion cooling system includes the components described above with respect to the prior art immersion cooling system of FIG. 1 (specifically, a chamber 200 having a bath of immersion coolant 202 and an ambient 204, and, a condenser 203 within the ambient). Additionally, however, the ambient 204 region of the chamber 200 is connected to the input 206 of a pump 205. The pumping action of the pump 205 draws air and vapor from the ambient 204 within the chamber 200 to form lower pressure on the liquid surface inside the chamber, which, in turn, lowers the pressure of the ambient 204. In various embodiments, with the exception of the fluidic connection to the pump 205, the chamber 200 is sealed (is “airtight”) so that the pressure of the ambient 205 drops in response to the intake draw from the pumping action of the pump 205.

The lowering of the ambient pressure lowers the boiling point of the immersion bath liquid 202. As described above, lowering the boiling point of the immersion bath 202 improves the heat transfer efficiency of the system, thereby allowing higher wattage electronics to be sufficiently cooled by the system.

As a consequence of the boiling activity within the chamber 200, the gaseous substance (e.g., “air”) drawn into the pump input 206 is apt to have some humidity/vapor (the ambient 204 contains small particles of the immersion bath liquid). As such, the air that is emitted at the pump output 207 is received by a condenser 208 (e.g., dehumidifier, heat exchanger, etc.) that removes the liquid from the air (e.g., by cooling it). The liquid is then returned to the coolant 202 region of the chamber 200.

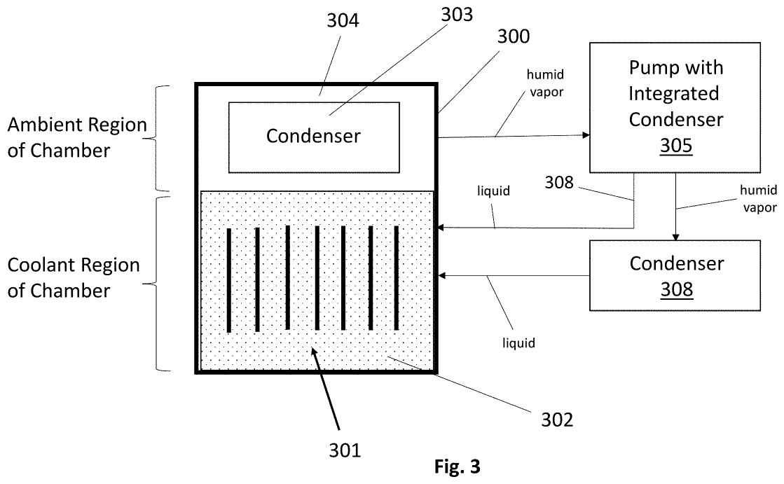

FIG. 3 shows another embodiment that integrates a condenser into the pump 305. The pump 305 therefore has a liquid output 308 that provides the liquid coolant that was extracted from the humid air that was drawn into the pump 305. The liquid coolant that is emitted from the liquid output 308 is then returned to the coolant 302 region of the chamber 300. If the condensation process that is performed within the pump 305 is not highly efficient, the pump also includes an air output as per the approach of FIG. 2. As such, also as per the approach of FIG. 2, the air emitted from the pump 205 is directed to a condenser 308 that condenses the liquid in the air and returns it to the coolant 302 region of the chamber 300. Again, the second condenser 308 need not exist if the pump's integrated condenser removes a sufficient amount of the intake air's vapor.

Liquids for two-phase immersion baths include Fluroinert™ electronic liquids FC-3284 and FC-72 and Novec™ engineering fluids 7000, 7100 and 7200 all from 3M Corporation of Maplewood, Minn. Each of these liquids are substantially inert and electrically insulating (dielectric). The Fluroinert™ products are fully-fluorinated liquids having specified boiling points of 50° C. (FC-3284) and 56° C. (FC-72) at atmospheric pressure. The Novec™ products are non-oil based liquids having boiling points of 34° C. (7000), 61° C. (7100) and 76° C. (7200) at atmospheric pressure. It is believed that the above specified boiling points of any of these liquids can be reduced by reducing ambient pressure in the coolant chamber 200, 300 as described at above with respect to FIGS. 2 and 3.

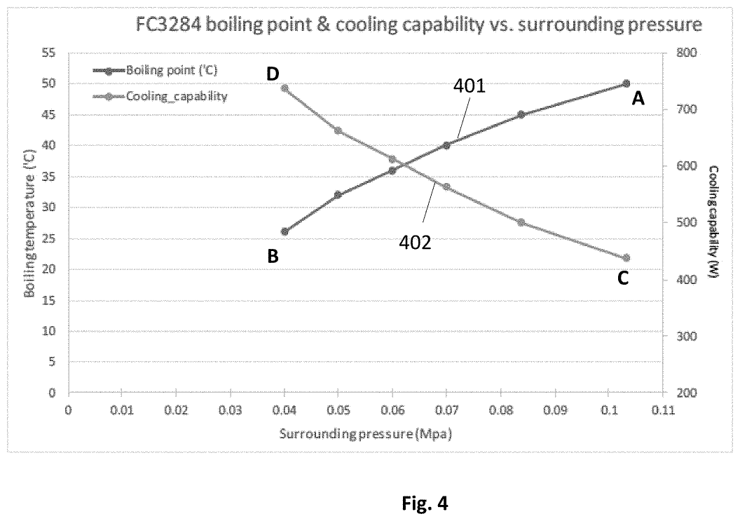

FIG. 4 provides data from an experimental system having approximately 1 m³ of FC-3284 coolant in the chamber and a “rough” vacuum pump. As can be seen in FIG. 4, the boiling point of the coolant was successfully lowered 401 from approximately 50° C. at atmospheric pressure (0.101 Mpa) (point A) to approximately 25° C. at 0.04 Megapascals (Mpa) (point B) through the pumping action of the vacuum pump. Also, as shown in FIG. 4, the lowering of the coolant's boiling point translates into a theoretical improvement in cooling capacity 402 from only 440 Watts (W) (point C) to 740 W (point D). Thus, it is believed that the cooling capacity of the system can be nearly doubled by halving the boiling point of the coolant.

In the specific experimental setup that generated the information of FIG. 4, the course vacuum pump could only reach a minimum ambient pressure of 0.04 Mpa within the chamber. If other, higher performance pumps are utilized that can achieve even lower ambient pressures, even lower boiling points are believed to be achievable with corresponding further improvement in cooling capacity. For example, ambient pressures as low as 0.02 Mpa or 0.01 Mpa or lower are achievable with corresponding thermal capacity improvements up to or even beyond 1000 W per 1 m³ of coolant.

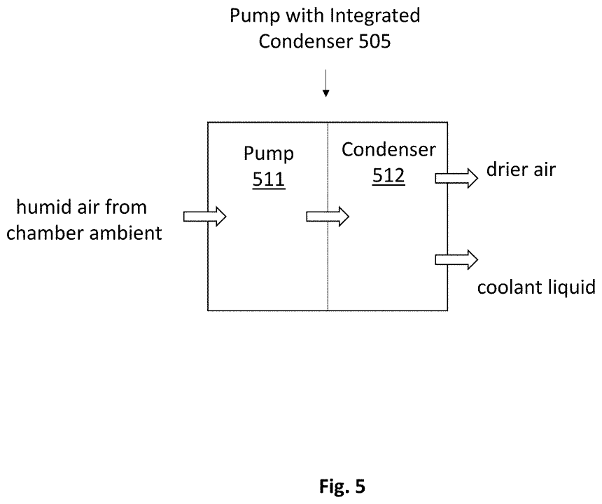

FIG. 5 shows a more detailed view of an embodiment of the integrated pump 305 of FIG. 3. As observed in FIG. 5, the integrated pump 505 includes a pump 511 and a condenser 512 in a single chassis or frame 505. The pump 505, like the pump 205 of FIG. 2, can be any of a number of different pump types that can exert suction on the chamber ambient. Examples include dynamic pumps (e.g., centrifugal) and positive displacement pumps (e.g., rotary and reciprocating). The condenser can be any apparatus that removes liquid from humid air (e.g., dehumidifier, heat exchanger, etc).

The integrated pump has two stages with the pump 511 being at a first stage and the condenser 512 being at a second stage. In operation, the input to the pump stage 511 draws on the humid air in the chamber to create a reduced boiling point coolant. The condenser stage 512 receives the humid air that has been pumped from the chamber ambient and removes the liquid coolant from it. As such, the condenser stage has a first output that provides drier air and a second output that provides the removed liquid coolant.

The liquid that the condenser removes from the air is provided at a liquid output and returned to the chamber. If the condenser stage 512 is highly efficient such that the air is mostly dried (has very little or no moisture), the dry output air is allowed to escape from the system. By contrast, if the condenser has lesser efficiency, the air output can be coupled to another condenser to extract the remaining liquid in the air and return the liquid to the chamber.

The cooling capacity curve 402 of FIG. 4 is calculated as provided in Equation 1 below:

$$Cooling Capacity ( W ) = \frac{T j max - B P}{P p k g + P c oolant} \qquad Eqn . 1$$

where; 1) Tjmax is the maximum allowed junction temperature of the electronic chip(s) being cooled by the cooling system (° C.); 2) BP is the boiling point of the liquid coolant (° C.); 3) Ppkg is the thermal resistance of the package from the heat source to the surface of the electronic package that the aforementioned chip(s) are packaged in (° C./W); and, 4) Pcoolant is the thermal resistance of the surrounding liquid coolant to the surface of the electronic device (° C./W).

The numerator of Eqn. 1 describes the pertinent temperatures when the semiconductor chip(s) are operating at maximum power and the coolant is boiling. The denominator of Eqn. 1 is a constant that describes the physical heat transfer characteristics of the thermal path from the semiconductor chip(s) to the ambient (first the heat travels through the chip package and then through the coolant). For the specific test apparatus that generated curve 401 of FIG. 4, Tjmax=85° C., Ppkg=0.05° C./W and Pcoolant=0.03° C./W.

Here, assuming that an electronic board having multiple semiconductor chips are immersed in the coolant bath, Eqn. 1 provides the maximum total electrical wattage of the board that could be cooled by the system (Tjmax and Ppkg are emblematic of the chips on the board and their packages). Notably, the numerator term increases as the boiling point decreases which corresponds to the improvement in thermal capacity that is observed with lowered coolant boiling point.

It is pertinent to point out that although “air” has been referred to as the gaseous content with the chamber, various alternative embodiments may employ or introduce other gaseous materials into the chamber such that the gaseous content within the chamber is something other than only “air”. As such, in a broader sense, the reader should understand that the teachings above apply more generally to embodiments where one or more substances in the gaseous phase are in the ambient region of the chamber.

It is also pertinent to point out that that the chamber can have many different shapes and sizes. In particular, for example, the ambient region of the chamber can have multiple bays or sub-chambers. For example, a first sub-chamber of the ambient region of the chamber physically interfaces with the liquid coolant and collects the vapor from the boiling coolant. The condenser, by contrast, is located in a second sub-chamber that is fluidly coupled to the first sub-chamber. Vapor flow from the first sub-chamber to the second-sub chamber to be condensed. The condensed liquid coolant is then returned to the coolant region of the chamber from the second sub-chamber. Chamber output(s) that is/are drawn upon by the pump can be in either or both of these sub-chambers, and/or in another (third) sub-chamber of the ambient region of the chamber.

Thus, the ambient region of the chamber can include multiple sub-chambers that, e.g., have open (or even valved) conduits between them. The coolant region of the chamber can also have many different sizes and shapes (e.g., a separate sub-chamber for each electronic circuit board that is immersed in the coolant contained by each sub-chamber).

Although the above teachings have been directed to a system that decreases chamber pressure to lower the boiling point of an immersion bath it is conceivable that a similar approach could be used to increase the pressure to raise the boiling point of an immersion bath (e.g., in the case where a candidate bath coolant has too low a boiling point for operable use). In this case a pump would pump into the chamber thereby raising the pressure and boiling point.

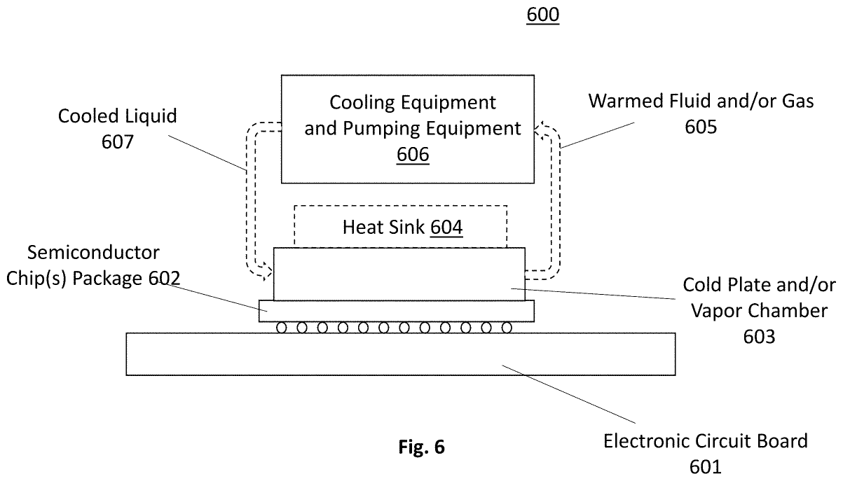

The teachings above can be applied to the cooling apparatus 600 of FIG. 6. FIG. 6 depicts a general cooling apparatus 600 whose features can be found in many different kinds of semiconductor chip cooling systems. As observed in FIG. 6, one or more semiconductor chips within a package 602 are mounted to an electronic circuit board 601. A cold plate 603 is thermally coupled with the package 602 (e.g., by being placed on the package 602 with a thermally conductive material (“thermal interface material”) between them) so that the cold plate 603 receives heat generated by the one or more semiconductor chips (the cold plate 603 can also be referred to as a vapor chamber in the case of two phase cooling systems).

Liquid coolant is within the cold plate 603. If the system also employs air cooling (optional), a heat sink 604 can be thermally coupled to the cold plate 603. Warmed liquid coolant and/or vapor 605 leaves the cold plate 603 to be cooled by one or more items of cooling equipment (e.g., heat exchanger(s), radiator(s), condenser(s), refrigeration unit(s), etc.) and pumped by one or more items of pumping equipment (e.g., dynamic (e.g., centrifugal), positive displacement (e.g., rotary, reciprocating, etc.)) 606. Cooled liquid 607 then enters the cold plate 603 and the process repeats.

With respect to the cooling equipment and pumping equipment 606, cooling activity can precede pumping activity, pumping activity can precede cooling activity, or multiple stages of one or both of pumping and cooling can be intermixed (e.g., in order of flow: a first cooling stage, a first pumping stage, a second cooling stage, a second pumping stage, etc.) and/or other combinations of cooling activity and pumping activity can take place.

Moreover, the intake of any equipment of the cooling equipment and pumping equipment 606 can be supplied by the cold plate of one semiconductor chip package or the respective cold plate(s) of multiple semiconductor chip packages.

In the case of the later (intake received from cold plate(s) of multiple semiconductor chip packages), the semiconductor chip packages can be components on a same electronic circuit board or multiple electronic circuit boards. In the case of the later (multiple electronic circuit boards), the multiple electronic circuit boards can be components of a same electronic system (e.g., different boards in a same server computer) or different electronic systems (e.g., electronic circuit boards from different server computers). In essence, the general depiction of FIG. 6 describes compact cooling systems (e.g., a cooling system contained within a single electronic system), expansive cooling systems (e.g., cooling systems that cool the components of any of a rack, multiple racks, a data center, etc.) and cooling systems in between.

FIG. 6 also describes immersion cooling systems where it is understood that the warmed fluid and/or vapor flow 605 is from the immersion bath chamber (not shown for illustrative ease) and the cooled fluid flow is 607 is into the immersion bath chamber.

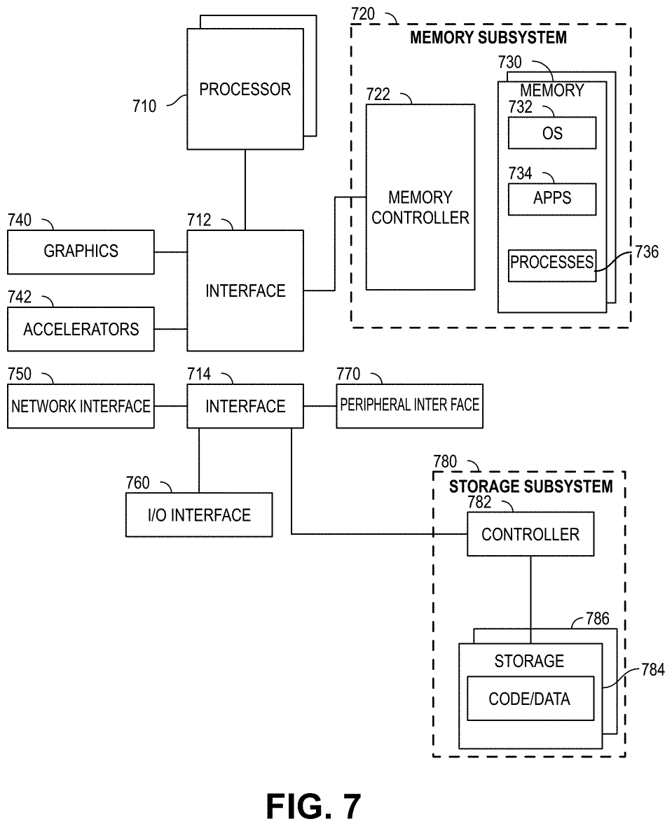

The following discussion concerning FIGS. 7, 8 and 9 are directed to systems, data centers and rack implementations, generally. It is pertinent to point out that any electronic component and/or electro-optic component and/or any electronic circuit board of any of the systems, data centers and rack implementations described below can be immersed in a coolant and cooled according to the reduced boiling point teachings discussed at length just above.

FIG. 7 depicts an example system. System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors to perform such networking functions (e.g., in a pipelined fashion or otherwise).

In one example, system 700 includes interface 712 coupled to processor 710, which can represent a higher speed interface or a high throughput interface for system components that needs higher bandwidth connections, such as memory subsystem 720 or graphics interface components 740, or accelerators 742. Interface 712 represents an interface circuit, which can be a standalone component or integrated onto a processor die. Where present, graphics interface 740 interfaces to graphics components for providing a visual display to a user of system 700. In one example, graphics interface 740 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 740 generates a display based on data stored in memory 730 or based on operations executed by processor 710 or both. In one example, graphics interface 740 generates a display based on data stored in memory 730 or based on operations executed by processor 710 or both.

Accelerators 742 can be a fixed function offload engine that can be accessed or used by a processor 710. For example, an accelerator among accelerators 742 can provide compression (DC) capability, cryptography services such as public key encryption (PKE), cipher, hash/authentication capabilities, decryption, or other capabilities or services. In some embodiments, in addition or alternatively, an accelerator among accelerators 742 provides field select controller capabilities as described herein. In some cases, accelerators 742 can be integrated into a CPU socket (e.g., a connector to a motherboard or circuit board that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic, and programmable processing elements such as field programmable gate arrays (FPGAs). Accelerators 742 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, volatile memory, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710. In some examples, a system on chip (SOC or SoC) combines into one SoC package one or more of: processors, graphics, memory, memory controller, and Input/Output (I/O) control logic.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 700 includes interface 714, which can be coupled to interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can transmit data to a remote device, which can include sending data stored in memory. Network interface 750 can receive data from a remote device, which can include storing received data into memory. Various embodiments can be used in connection with network interface 750, processor 710, and memory subsystem 720.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data in a persistent state (e.g., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 714 or processor 710 or can include circuits or logic in both processor 710 and interface 714.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 700. More specifically, power source typically interfaces to one or multiple power supplies in system 700 to provide power to the components of system 700. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 700 can be implemented as a disaggregated computing system. For example, the system 700 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.). The system can be at the periphery of a network to add computing power at the network periphery (edge computing). The system can also be a system that is expected to face extreme temperatures (e.g., the system is or is part of a base station that sits outside on cellular shelf).

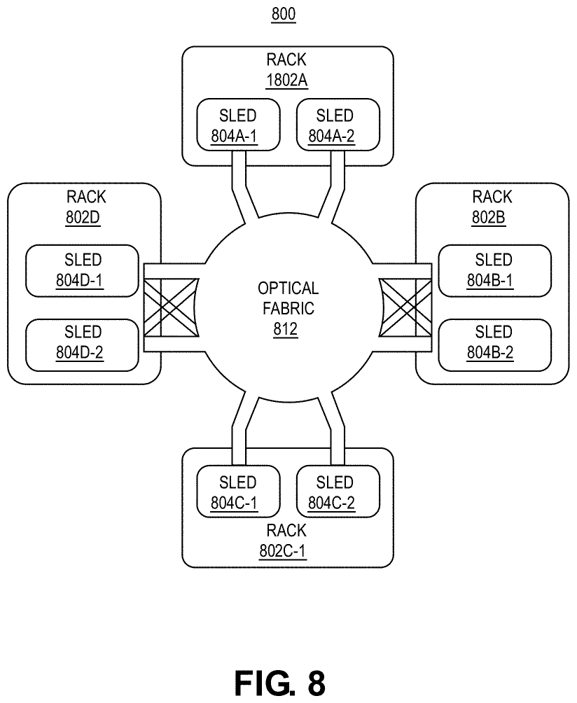

FIG. 8 depicts an example of a data center. Various embodiments can be used in or with the data center of FIG. 8. As shown in FIG. 8, data center 800 may include an optical fabric 812. Optical fabric 812 may generally include a combination of optical signaling media (such as optical cabling) and optical switching infrastructure via which any particular sled in data center 800 can send signals to (and receive signals from) the other sleds in data center 800. However, optical, wireless, and/or electrical signals can be transmitted using fabric 812. The signaling connectivity that optical fabric 812 provides to any given sled may include connectivity both to other sleds in a same rack and sleds in other racks.

Data center 800 includes four racks 802A to 802D and racks 802A to 802D house respective pairs of sleds 804A-1 and 804A-2, 804B-1 and 804B-2, 804C-1 and 804C-2, and 804D-1 and 804D-2. Thus, in this example, data center 800 includes a total of eight sleds. Optical fabric 812 can provide sled signaling connectivity with one or more of the seven other sleds. For example, via optical fabric 812, sled 804A-1 in rack 802A may possess signaling connectivity with sled 804A-2 in rack 802A, as well as the six other sleds 804B-1, 804B-2, 804C-1, 804C-2, 804D-1, and 804D-2 that are distributed among the other racks 802B, 802C, and 802D of data center 800. The embodiments are not limited to this example. For example, fabric 812 can provide optical and/or electrical signaling.

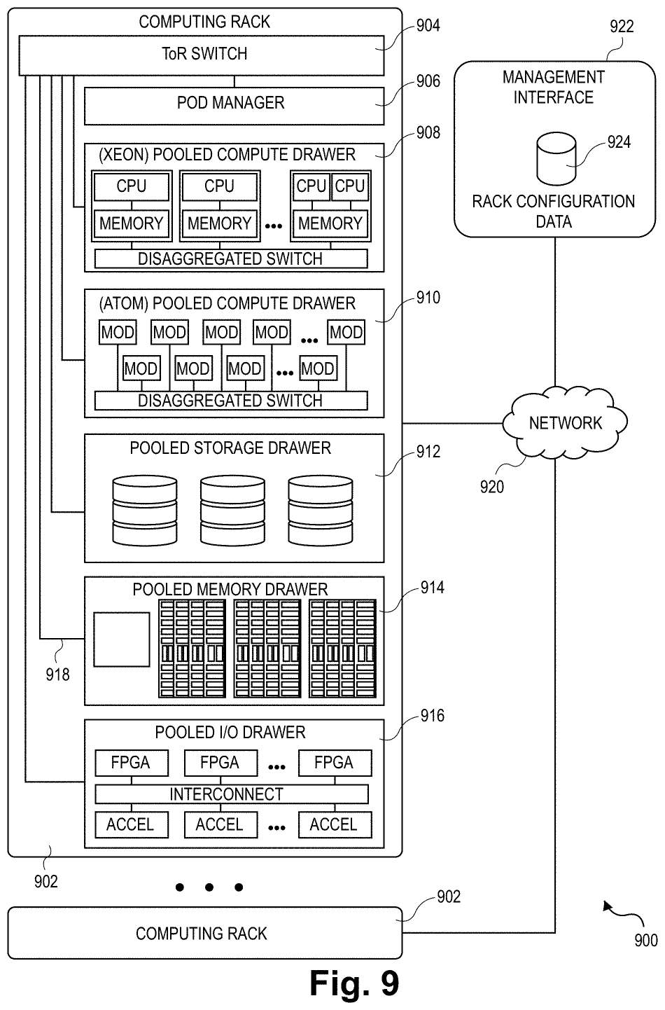

FIG. 9 depicts an environment 900 that includes multiple computing racks 902, each including a Top of Rack (ToR) switch 904, a pod manager 906, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 908, and INTEL® ATOM′″ pooled compute drawer 910, a pooled storage drawer 912, a pooled memory drawer 914, and a pooled I/O drawer 916. Each of the pooled system drawers is connected to ToR switch 904 via a high-speed link 918, such as a 40 Gigabit/second (Gb/s) or 100 Gb/s Ethernet link or an 100+Gb/s Silicon Photonics (SiPh) optical link. In one embodiment high-speed link 918 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 900 may be interconnected via their ToR switches 904 (e.g., to a pod-level switch or data center switch), as illustrated by connections to a network 920. In some embodiments, groups of computing racks 902 are managed as separate pods via pod manager(s) 906. In one embodiment, a single pod manager is used to manage all of the racks in the pod. Alternatively, distributed pod managers may be used for pod management operations. RSD environment 900 further includes a management interface 922 that is used to manage various aspects of the RSD environment. This includes managing rack configuration, with corresponding parameters stored as rack configuration data 924.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1. An apparatus, comprising:
an immersion cooling system, comprising:
a) a chamber;
b) a condenser to cool vapor in an ambient region of the chamber when the chamber contains a liquid coolant that is boiling in a liquid coolant region of the chamber;
c) a pump to draw from the ambient region of the chamber to reduce a pressure of the ambient region of the chamber, wherein, the pressure of the ambient region of the chamber is reduced to reduce a boiling point of the liquid coolant, wherein, the boiling point of the liquid coolant is reduced to increase a cooling capacity of the immersion cooling system.

2. The apparatus of claim 1 further comprising another condenser to receive gas from a gas output of the pump and to provide the liquid coolant to the coolant region of the chamber.

3. The apparatus of claim 1 wherein another condenser is integrated within the pump.

4. The apparatus of claim 3 further comprising a fluid output of the pump to provide the liquid coolant extracted by the another condenser to the coolant region of the chamber.

5. The apparatus of claim 1 wherein the cooling capacity of the immersion cooling system is to be at least 740 W/m³ of the liquid coolant.

6. The apparatus of claim 5 wherein the cooling capacity of the immersion cooling system is to be at least 1000 W/m³ of the liquid coolant.

7. The apparatus of claim 1 wherein the pressure of the ambient region of the chamber is to be reduced to 0.04 Mpa or lower.

8. A data center, comprising:
multiple computing systems communicatively coupled by a network, wherein, at least one of the computing systems comprises an electronic circuit board having electronic components, the electronic printed circuit board immersed in a liquid coolant of an immersion cooling system of the data center, the immersion cooling system comprising:
a) a chamber containing the liquid coolant;
b) a condenser to cool vapor in an ambient region of the chamber when the liquid coolant is boiling in a liquid coolant region of the chamber;
c) a pump to draw from the ambient region of the chamber to reduce a pressure of the ambient region of the chamber, wherein, the pressure of the ambient region of the chamber is reduced to reduce a boiling point of the liquid coolant, wherein, the boiling point of the liquid coolant is reduced to increase a cooling capacity of the immersion cooling system.

9. The data center of claim 8 further comprising another condenser to receive gas from a gas output of the pump and to provide the liquid coolant to the coolant region of the chamber.

10. The data center of claim 8 wherein another condenser is integrated within the pump.

11. The data center of claim 10 further comprising a fluid output of the pump to provide the liquid coolant extracted by the another condenser to the coolant region of the chamber.

12. The data center of claim 8 wherein the cooling capacity of the immersion cooling system is to be at least 740 W/m³ of the liquid coolant.

13. The data center of claim 12 wherein the cooling capacity of the immersion cooling system is to be at least 1000 W/m³ of the liquid coolant.

14. The data center of claim 8 wherein the pressure of the ambient region of the chamber is to be reduced to 0.04 Mpa or lower.

15. A method of operating an immersion cooling system, comprising:
operating one or more electronic components that are immersed in a liquid coolant, the operating of the one or more electronic components causing the liquid coolant to boil;
condensing vapor from the boiling liquid coolant in an ambient region of a chamber;
drawing gas from the ambient region of the chamber to reduce a pressure of the gas within the ambient region of the chamber, the reduction of the pressure of the gas to reduce a boiling point of the liquid coolant, the reduction of the boiling point of the liquid coolant to increase the cooling capacity of the immersion cooling system.

16. The method of claim 15 wherein the drawing of the gas is performed by an operating pump.

17. The method of claim 16 further comprising:
the pump providing condensed liquid coolant;
returning the liquid coolant to a coolant region of the chamber.

18. The method of claim 16 further comprising:
the pump providing dried gas;
condensing the dried gas to provide condensed liquid coolant; and,
returning the condensed liquid coolant to a coolant region of the chamber.

19. The method of claim 15 wherein the cooling capacity of the immersion cooling system is at least 740 W/m³ of the liquid coolant within a liquid coolant region of the chamber.

20. The method of claim 15 wherein the pressure of the ambient region of the chamber is 0.04 Mpa or lower.
